(19) United States
(12) Patent Application Publication
(10) Pub. No.: US 2023/0013102 A1
(43) Pub. Date: Jan. 19, 2023

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Hung-Chih WANG, Hsinchu (TW); Hsin-Jung CHANG, Taichung (TW); Chun-Chih LIN, Taipei (TW); Su-Yu YEH, Tainan (TW)

(21) Appl. No.: 17/736,076

(22) Filed: May 3, 2022

Related U.S. Application Data
(60) Provisional application No. 63/222,654, filed on Jul. 16, 2021.

(51) Int. Cl. H01L 23/522; H01L 21/768

(52) U.S. Cl. CPC H01L 23/5226; H01L 21/7684; H01L 21/76802; H01L 21/76826; H01L 21/76831; H01L 21/76877

(57) ABSTRACT

Methods of forming a semiconductor device structure are described. The method includes forming a first conductive feature including a conductive fill material over a substrate, forming an etch stop layer on the conductive fill material, forming an intermetallization dielectric on the etch stop layer, forming an opening in the etch stop layer and the intermetallization dielectric to expose a portion of the conductive fill material, forming a recess in the exposed portion of the conductive fill material, and the opening and the recess together form a rivet-shaped space. The method further includes forming a second conductive feature in the rivet-shaped space and forming a metal nitride layer over the intermetallization dielectric and the second conductive feature. The forming the metal nitride layer includes depositing the metal nitride layer and treating the metal nitride layer with a plasma treatment process.

### CROSS-REFERENCE TO RELATED APPLICATIONS

This application claims priority to U.S. Provisional Application No. 63/222,654, filed on Jul. 16, 2021, the contents of which are hereby incorporated by reference in their entirety.

### BACKGROUND

The semiconductor integrated circuit (IC) industry has experienced exponential growth. Technological advances in IC materials and design have produced generation of ICs where each generation has smaller and more complex circuits than the previous generation. In the course of IC evolution, functional density (e.g., the number of interconnected devices per chip area) has generally increased while geometry size (e.g., the smallest component (or line) that can be created using a fabrication process) has decreased. This scaling down process generally provides benefits by increasing production efficiency and lowering associated costs.

Accompanying the scaling down of devices, manufacturers have begun using new and different materials and/or combination of materials to facilitate the scaling down of devices. Scaling down, alone and in combination with new and different materials, has also led to challenges that may not have been presented by previous generations at larger geometries.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device structure, in accordance with some embodiments.

FIGS. 2 - 9 are cross-sectional side views of various stages of manufacturing the semiconductor device structure of FIG. 1 taken along cross-section A-A, in accordance with some embodiments.

FIGS. 10 - 18 are enlarged views of portions of the semiconductor device structure during various manufacturing stages, in accordance with some embodiments.

FIGS. 19A and 19B are enlarged views of a portion of a metal nitride layer, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Generally, the present disclosure provides example embodiments relating to conductive features, such as metal contacts, vias, lines, etc., and methods for forming those conductive features. Example embodiments described herein are described in the context of forming conductive features in back end of the line (BEOL) and/or middle end of the line (MEOL) processing for a fin field effect transistor (FinFET). Other embodiments may be implemented in other contexts, such as with different devices, such as planar field effect transistors (FETs), vertical gate all around (VGAA) FETs, horizontal gate all around (HGAA) FETs, bipolar junction transistors (BJTs), diodes, capacitors, inductors, resistors, etc. Implementations of some aspects of the present disclosure may be used in other processes and/or in other devices.

Some variation of the example methods and structures are described. A person having ordinary skill in the art will readily understand other modifications that may be made that are contemplated within the scope of other embodiments. Although method embodiments may be described in a particular order, various other method embodiments may be performed in any logical order and may include fewer or more steps than what is described herein. In some figures, some reference numbers of components or features illustrated therein may be omitted to avoid obscuring other components or features; this is for ease of depicting the figures.

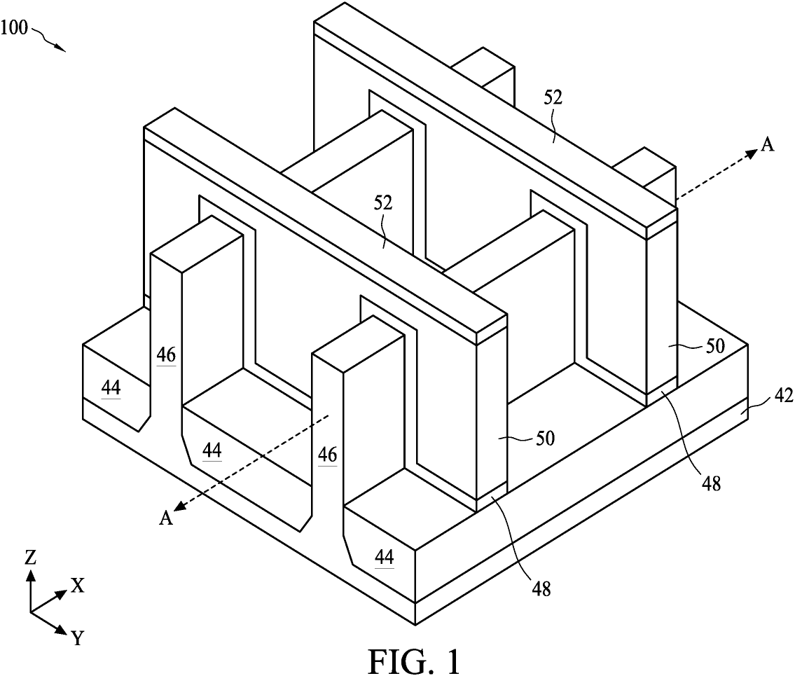

FIGS. 1 through 9 illustrate views of respective semiconductor device structure 100 at respective stages during an example method for forming conductive features in accordance with some embodiments. FIG. 1 illustrates a perspective view of the semiconductor device structure at a stage of the example method. The semiconductor device structure 100, as described in the following, is used in the implementation of FinFETs. Other structures may be implemented in other example embodiments.

The semiconductor device structure 100 includes first and second fins 46 formed on a semiconductor substrate 42, with respective isolation regions 44 on the semiconductor substrate 42 between neighboring fins 46. First and second dummy gate stacks are along respective sidewalls of and over the fins 46. The first and second dummy gate stacks each include an interfacial dielectric 48, a dummy gate 50, and a mask 52.

The semiconductor substrate 42 may be or include a bulk semiconductor substrate, a semiconductor-on-insulator (SOI) substrate, or the like, which may be doped (e.g., with a p-type or an n-type dopant) or undoped. In some embodiments, the semiconductor material of the semiconductor substrate 42 may include an elemental semiconductor such as silicon (Si) or germanium (Ge); a compound semiconductor; an alloy semiconductor; or a combination thereof.

The fins 46 are formed in the semiconductor substrate 42. For example, the semiconductor substrate 42 may be etched, such as by appropriate photolithography and etch process, such that trenches are formed between neighboring pairs of fins 46 and such that the fins 46 protrude from the semiconductor substrate 42. Isolation regions 44 are formed with each being in a corresponding trench. The isolation regions 44 may include or be an insulating material such as an oxide (such as silicon oxide), a nitride, the like, or a combination thereof. The insulating material may then be recessed after being deposited to form the isolation regions 44. The insulating material is recessed using an acceptable etch process such that the fins 46 protrude from between neighboring isolation regions 44, which may, at least in part, thereby delineate the fins 46 as active areas on the semiconductor substrate 42. The fins 46 may be formed by other processes, and may include homoepitaxial and/or heteroepitaxial structures, for example.

The dummy gate stacks are formed on the fins 46. In a replacement gate process as described herein, the interfacial dielectrics 48, dummy gates 50, and masks 52 for the dummy gate stacks may be formed by sequentially forming respective layers by appropriate deposition processes, for example, and then patterning those layers into the dummy gate stacks by appropriate photolithography and etch processes. For example, the interfacial dielectrics 48 may include or be silicon oxide, silicon nitride, the like, or multilayers thereof. The dummy gates 50 may include or be silicon (e.g., polysilicon) or another material. The masks 52 may include or be silicon nitride, silicon oxynitride, silicon carbon nitride, the like, or a combination thereof.

In other examples, instead of and/or in addition to the dummy gate stacks, the gate stacks can be operational gate stacks (or more generally, gate structures) in a gate-first process. In a gate-first process, the interfacial dielectric 48 may be a gate dielectric layer, and the dummy gate 50 may be a gate electrode. The gate dielectric layers, gate electrodes, and masks 52 for the operational gate stacks may be formed by sequentially forming respective layers by appropriate deposition processes, and then patterning those layers into the gate stacks by appropriate photolithography and etch processes. For example, the gate dielectric layers may include or be silicon oxide, silicon nitride, a high-k dielectric material, the like, or multilayers thereof. A high-k dielectric material may have a k value greater than about 7.0, and may include a metal oxide of or a metal silicate of hafnium (Hf), aluminum (Al), zirconium (Zr), lanthanum (La), magnesium (Mg), barium (Ba), titanium (Ti), lead (Pb), multilayers thereof, or a combination thereof. The gate electrodes may include or be silicon (e.g., polysilicon, which may be doped or undoped), a metal-containing material (such as titanium, tungsten, aluminum, ruthenium, or the like), a combination thereof (such as a silicide (which may be subsequently formed), or multiple layers thereof. The masks 52 may include or be silicon nitride, silicon oxynitride, silicon carbon nitride, the like, or a combination thereof.

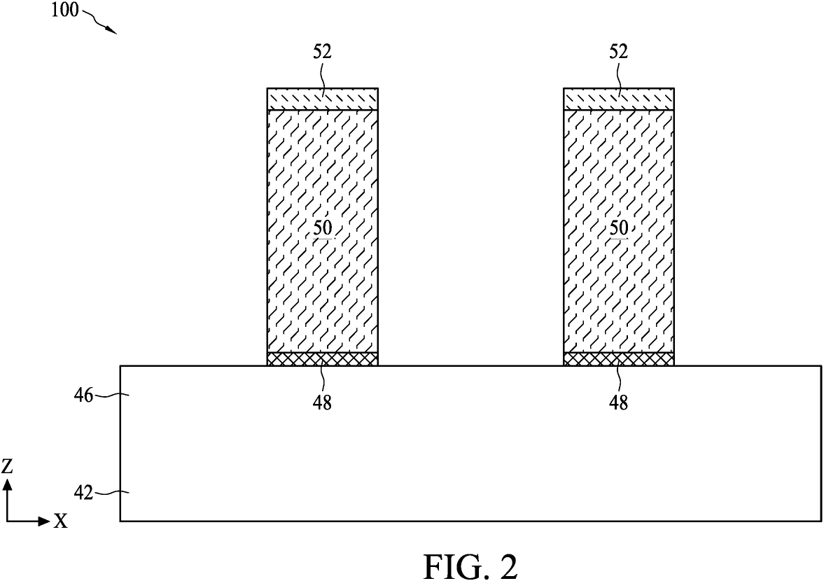

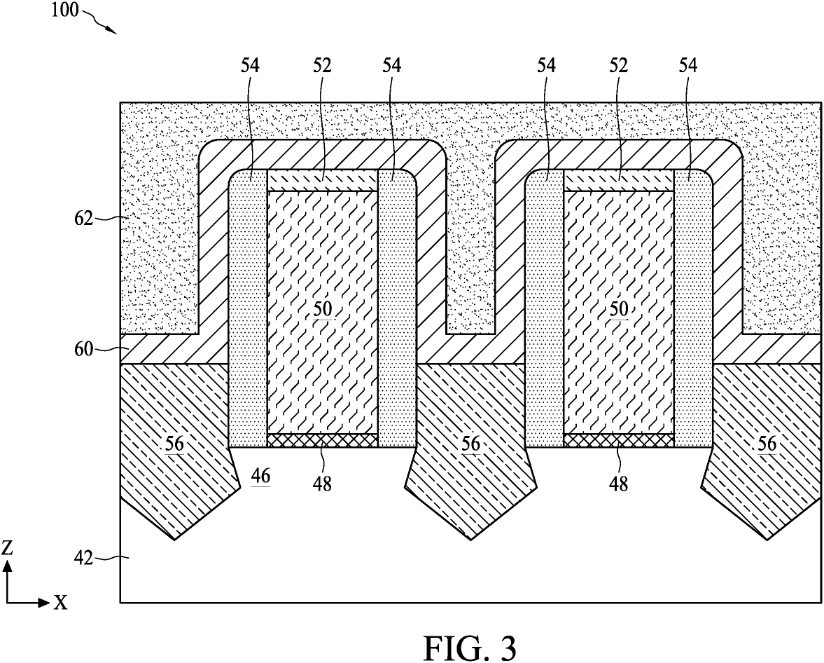

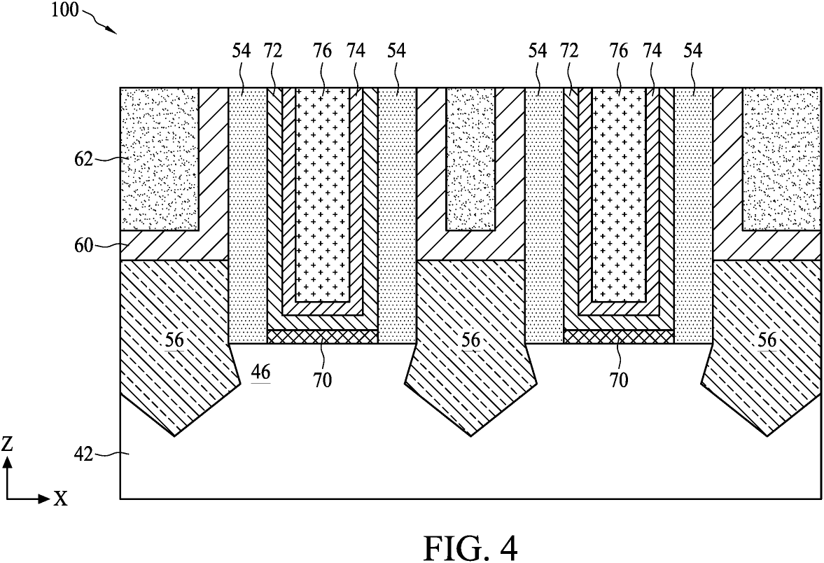

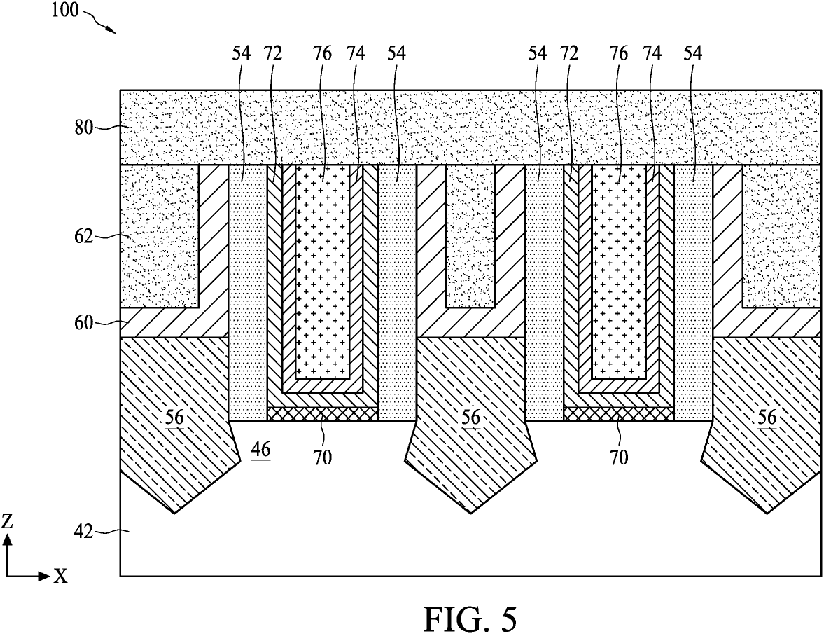

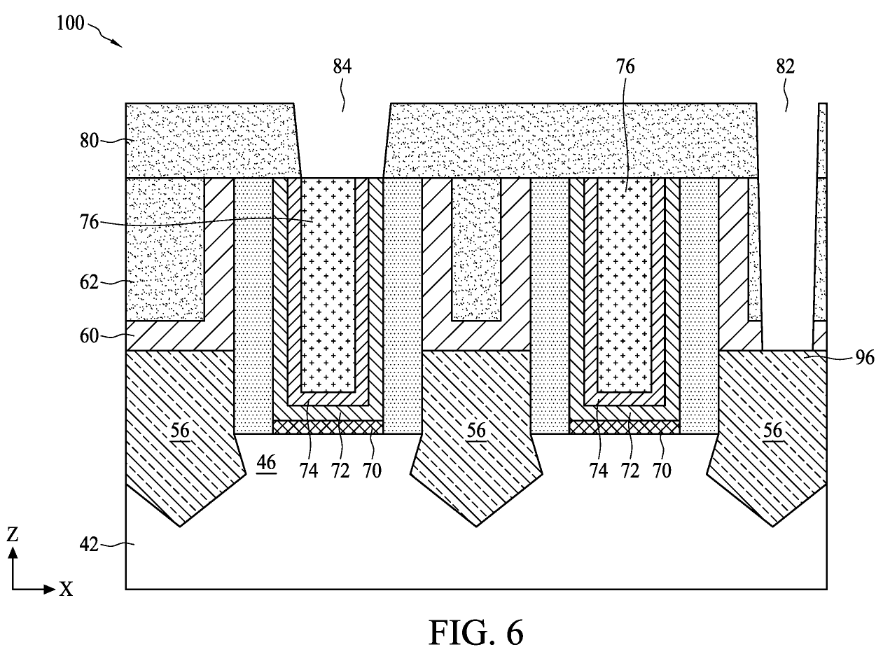

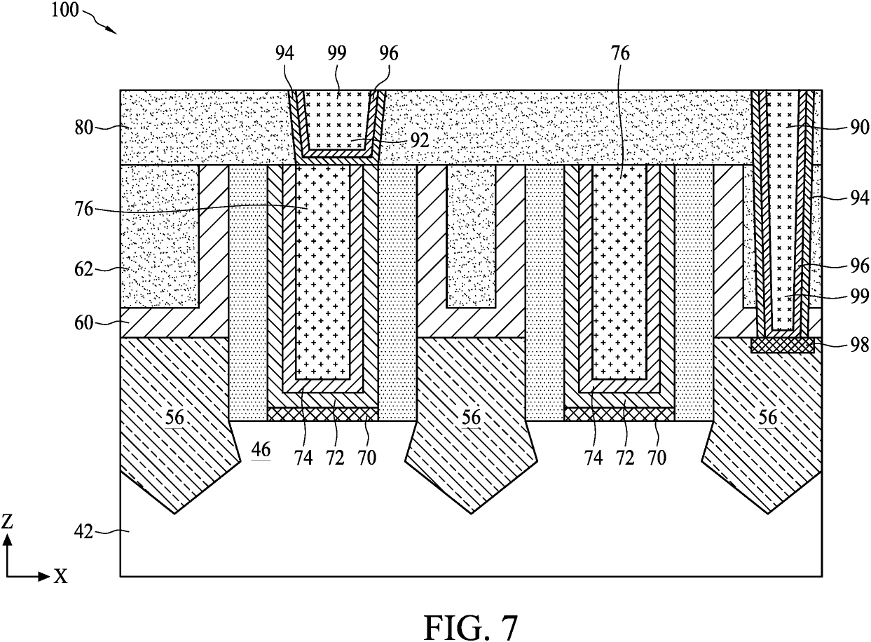

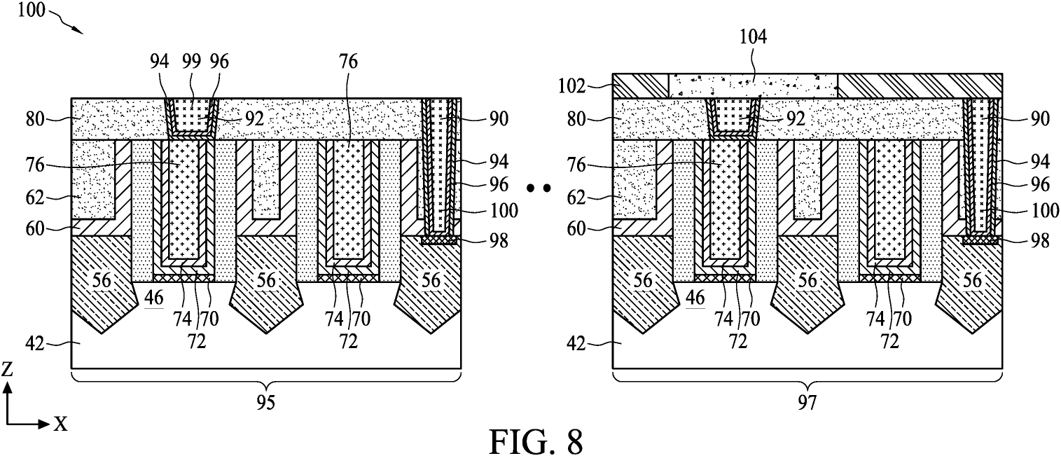

FIG. 1 further illustrates a reference cross-section that is used in later figures. Cross-section A-A is in a plane along, e.g., channels in the fin 46 between opposing source/drain regions. The FIGS. 2 through 10 illustrate cross-sectional views at various stages of processing in various example methods corresponding to cross-section A-A. FIG. 2 illustrates a cross-sectional view of the semiconductor device structure 100 of FIG. 1 at the cross-section A-A.

FIG. 3 illustrates the formation of gate spacers 54, epitaxy source/drain regions 56, a contact etch stop layer (CESL) 60, and a first interlayer dielectric (ILD) 62. Gate spacers 54 are formed along sidewalls of the dummy gate stacks (e.g., sidewalls of the interfacial dielectrics 48, dummy gates 50, and masks 52) and over the fins 46. The gate spacers 54 may be formed by conformally depositing, by an appropriate deposition process, one or more layers for the gate spacers 54 and anisotropically etching the one or more layers, for example. The one or more layers for the gate spacers 54 may include or be silicon oxygen carbide, silicon nitride, silicon oxynitride, silicon carbon nitride, the like, multi-layers thereof, or a combination thereof.

Recesses are then formed in the fins 46 on opposing sides of the dummy gate stacks (e.g., using the dummy gate stacks and gate spacers 54 as a mask) by an etch process. The etch process can be isotropic or anisotropic, or further, may be selective with respect to one or more crystalline planes of the semiconductor substrate 42. Hence, the recesses can have various cross-sectional profiles based on the etch process implemented. The epitaxy source/drain regions 56 are formed in the recesses. The epitaxy source/drain regions 56 may include or be silicon germanium, silicon carbide, silicon phosphorus, silicon carbon phosphorus, pure or substantially pure germanium, a III-V compound semiconductor, a II-VI compound semiconductor, or the like. The epitaxy source/drain regions 56 may be formed in the recesses by an appropriate epitaxial growth or deposition process. In some examples, epitaxy source/drain regions 56 can be raised with respect to the fin 46, and can have facets, which may correspond to crystalline planes of the semiconductor substrate 42.

A person having ordinary skill in the art will also readily understand that the recessing and epitaxial growth may be omitted, and that source/drain regions may be formed by implanting dopants into the fins 46 using the dummy gate stacks and gate spacers 54 as masks. In some examples where epitaxy source/drain regions 56 are implemented, the epitaxy source/drain regions 56 may also be doped, such as by in situ doping during epitaxial growth and/or by implanting dopants into the epitaxy source/drain regions 56 after epitaxial growth. Hence, a source/drain region may be delineated by doping (e.g., by implantation and/or in situ during epitaxial growth, if appropriate) and/or by epitaxial growth, if appropriate, which may further delineate the active area in which the source/drain region is delineated.

The CESL 60 is conformally deposited, by an appropriate deposition process, on surfaces of the epitaxy source/drain regions 56, sidewalls and top surfaces of the gate spacers 54, top surfaces of the masks 52, and top surfaces of the isolation regions 44. Generally, an etch stop layer (ESL) can provide a mechanism to stop an etch process when forming, e.g., contacts or vias. An ESL may be formed of a dielectric material having a different etch selectively from adjacent layers or components. The CESL 60 may include or be silicon nitride, silicon carbon nitride, silicon carbon oxide, carbon nitride, the like, or a combination thereof.

The first ILD 62 is deposited, by an appropriate deposition process, on the CESL 60. The first ILD 62 may comprise or be silicon dioxide, a low-k dielectric material (e.g., a material having a dielectric constant lower than silicon dioxide), silicon oxynitride, phosphosilicate glass (PSG), borosilicate glass (BSG), borophosphosilicate glass (BPSG), undoped silicate glass (USG), fluorinated silicate glass (FSG), organosilicate glasses (OSG), SiOₓC_{y}, spin-on-glass, spin-on-polymers, silicon carbon material, a compound thereof, a composite thereof, the like, or a combination thereof.

The first ILD 62 may be planarized after being deposited, such as by a chemical mechanical planarization (CMP). In a gate-first process, a top surface of the first ILD 62 may be above the upper portions of the CESL 60 and the gate stacks, and processing described below with respect to FIGS. 4 and 5 may be omitted. Hence, the upper portions of the CESL 60 and first ILD 62 may remain over the gate stacks.

FIG. 4 illustrates the replacement of the dummy gate stacks with replacement gate structures. The first ILD 62 and CESL 60 are formed with top surfaces coplanar with top surfaces of the dummy gates 50. A planarization process, such as a CMP, may be performed to level the top surfaces of the first ILD 62 and CESL 60 with the top surfaces of the dummy gates 50. The CMP may also remove the masks 52 (and, in some instances, upper portions of the gate spacers 54) on the dummy gates 50. Accordingly, top surfaces of the dummy gates 50 are exposed through the first ILD 62 and the CESL 60.

With the dummy gates 50 exposed through the first ILD 62 and the CESL 60, the dummy gates 50 are removed, such as by one or more etch processes. The dummy gates 50 may be removed by an etch process selective to the dummy gates 50, where the interfacial dielectrics 48 act as ESLs, and subsequently, the interfacial dielectrics 48 can optionally be removed by a different etch process selective to the interfacial dielectrics 48. Recesses are formed between gate spacers 54 where the dummy gate stacks are removed, and channel regions of the fins 46 are exposed through the recesses.

The replacement gate structures are formed in the recesses where the dummy gate stacks were removed. The replacement gate structures each include, as illustrated, an interfacial dielectric 70, a gate dielectric layer 72, one or more optional conformal layers 74, and a gate conductive fill material 76. The interfacial dielectric 70 is formed on sidewalls and top surfaces of the fins 46 along the channel regions. The interfacial dielectric 70 is formed on sidewalls and top surfaces of the fins 46 along the channel regions. The interfacial dielectric 70 can be, for example, the interfacial dielectric 48 if not removed, an oxide (e.g., silicon oxide) formed by thermal or chemical oxidation of the fin 46, and/or an oxide (e.g., silicon oxide), nitride (e.g., silicon nitride), and/or another dielectric layer.

The gate dielectric layer 72 can be conformally deposited in the recesses where dummy gate stacks were removed (e.g., on top surfaces of the isolation regions 44, on the interfacial dielectric 70, and sidewalls of the gate spacers 54) and on the top surfaces of the first ILD 62, the CESL 60, and gate spacers 54. The gate dielectric layer 72 can be or include silicon oxide, silicon nitride, a high-k dielectric material (examples of which are provided above), multilayers thereof, or other dielectric material.

Then, the one or more optional conformal layers 74 can be conformally (and sequentially, if more than one) deposited on the gate dielectric layer 72. The one or more optional conformal layers 74 can include one or more barrier and/or capping layers and one or more work-function tuning layers. The one or more barrier and/or capping layers can include a nitride, silicon nitride, carbon nitride, and/or aluminum nitride of tantalum and/or titanium; a nitride, carbon nitride, and/or carbide of tungsten; the like; or a combination thereof. The one or more work-function tuning layer may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

A layer for the gate conductive fill material 76 is formed over the one or more optional conformal layers 74 (e.g., over the one or more work-function tuning layers), if implemented, and/or the gate dielectric layer 72. The layer for the gate conductive fill material 76 can fill remaining recesses where the dummy gate stacks were removed. The layer for the gate conductive fill material 76 may be or include a metal-containing material such as tungsten, cobalt, aluminum, ruthenium, copper, multi-layers thereof, a combination thereof, or the like. Portions of the layer for the gate conductive fill material 76, one or more optional conformal layers 74, and gate dielectric layer 72 above the top surfaces of the first ILD 62, the CESL 60, and gate spacers 54 are removed, such as by a CMP. The replacement gate structures including the gate conductive fill material 76, one or more optional conformal layers 74, gate dielectric layer 72, and interfacial dielectric 70 may therefore be formed as illustrated in FIG. 4.

FIG. 5 illustrates the formation of a second ILD 80 over the first ILD 62, CESL 60, gate spacers 54, and replacement gate structures. Although not illustrated, in some examples, an ESL may be deposited over the first ILD 62, etc., and the second ILD 80 may be deposited over the ESL. If implemented, the ESL may include or be silicon nitride, silicon carbon nitride, silicon carbon oxide, carbon nitride, the like, or a combination thereof. The second ILD 80 may include or be silicon dioxide, a low-k dielectric material, silicon oxynitride, PSG, BSG, BPSG, USG, FSG, OSG, SiOₓC_{y}, spin-on-glass, spin-on-polymers, silicon carbon material, a compound thereof, a composite thereof, the like, or a combination thereof.

FIG. 6 illustrates the formation of openings 82 and 84 (one of each is shown). The openings 82 are formed through the second ILD 80, the first ILD 62, and the CESL 60 to expose at least a portion of an epitaxy source/drain region 56, and the openings 84 are formed through the second ILD 80 to expose at least a portion of the gate conductive fill material 76. The second ILD 80, the first ILD 62, and the CESL 60 may be patterned, for example, using photolithography and one or more etch processes, to form the openings 82 and 84.

FIG. 7 illustrates the formation of conductive features 90 and 92 in the openings 82 and 84, respectively. The conductive feature 90 includes, in the illustrated example, an adhesion layer 94, a barrier layer 96 on the adhesion layer 94, a silicide region 98 on the epitaxy source/drain region 56, and a conductive fill material 99 on the barrier layer 96, for example. The conductive feature 92 includes, in the illustrated example, an adhesion layer 94, a barrier layer 96 on the adhesion layer 94, and conductive fill material 99 on the barrier layer 96, for example.

The adhesion layer 94 can be conformally deposited in the openings 82 and 84 (e.g., on sidewalls of the openings 82 and 84, exposed surface of the epitaxy source/drain region 56, and exposed surface of the replacement gate structure) and over the second ILD 80. The adhesion layer 94 may be or include titanium, tantalum, the like, or a combination thereof, and may be deposited by atomic layer deposition (ALD), chemical vapor deposition (CVD), physical vapor deposition (PVD), or another deposition technique. The barrier layer 96 can be conformally deposited on the adhesion layer 94, such as in the openings 82 and 84 and over the second ILD 80. The barrier layer 96 may be or include titanium nitride, titanium oxide, tantalum nitride, tantalum oxide, the like, or a combination thereof, and may be deposited by ALD, CVD, or another deposition technique. In some examples, at least a portion of the adhesion layer 94 can be treated to form the barrier layer 96. For example, a nitridation process, such as including a nitrogen plasma process, can be performed on the adhesion layer 94 to convert at least the portion of the adhesion layer 94 into the barrier layer 96. In some examples, the adhesion layer 94 can be completely converted such that no adhesion layer 94 remains and the barrier layer 96 is an adhesion/barrier layer, while in other examples, a portion of the adhesion layer 94 remains unconverted such that the portion of the adhesion layer 94 remains with the barrier layer 96 on the adhesion layer 94.

The silicide region 98 may be formed on the epitaxy source/drain region 56 by reacting an upper portion of the epitaxy source/drain region 56 with the adhesion layer 94, and possibly, the barrier layer 96. An anneal can be performed to facilitate the reaction of the epitaxy source/drain region 56 with the adhesion layer 94 and/or barrier layer 96.

The conductive fill material 99 can be deposited on the barrier layer 96 and fill the openings 82 and 84. The conductive fill material 99 may be or include cobalt, tungsten, copper, ruthenium, aluminum, gold, silver, alloys thereof, the like, or a combination thereof, and may be deposited by CVD, ALD, PVD, or another deposition technique. After the conductive fill material 99 is deposited, excess conductive fill material 99, barrier layer 96, and adhesion layer 94 may be removed by using a planarization process, such as a CMP, for example. The planarization process may remove excess conductive fill material 99, barrier layer 96, and adhesion layer 94 from above a top surface of the second ILD 80. Hence, top surfaces of the conductive features 90 and 92 and the second ILD 80 may be coplanar. The conductive features 90 and 92 may be or may be referred to as contacts, plugs, etc.

Although FIGS. 6 and 7 illustrate the conductive features 90 and 92 being formed simultaneously, the conductive features 90 and 92 may be formed separately and sequentially. For example, the opening 82 may be first formed, as shown in FIG. 6, and filled to form the conductive feature 90, as shown in FIG. 7. Then, the opening 84 may be formed, as shown in FIG. 6, and filled to form the conductive feature 92, as shown in FIG. 7. Another order of processing may be implemented.

FIG. 8 illustrates portions of the semiconductor device structure 100 disposed over different regions of the semiconductor substrate 42. For example, the portion of the semiconductor device structure 100 shown on the left is an active region 95, while the portion of the semiconductor device structure 100 shown on the right is a resistor region 97. In some embodiments, a dielectric layer 102 is formed on the second ILD 80 in the resistor region 97, and a resistor layer 104 is formed in the dielectric layer 102. The dielectric layer 102 may include the same material as the second ILD 80 and may be formed by the same process as the second ILD 80. The resistor layer 104 may be or include TiN or TaN and may be formed by any suitable process. A mask layer (not shown) may be formed on the second ILD 80 in the active region 95. The dielectric layer 102 and the resistor layer 104 may be formed on the mask layer in the active region 95, and the portions of the dielectric layer 102 and the resistor layer 104 formed on the mask layer in the active region 95 may be removed by a CMP process. The mask layer may be removed by any suitable process after the formation of the dielectric layer 102 and the resistor layer 104 in the resistor region 97.

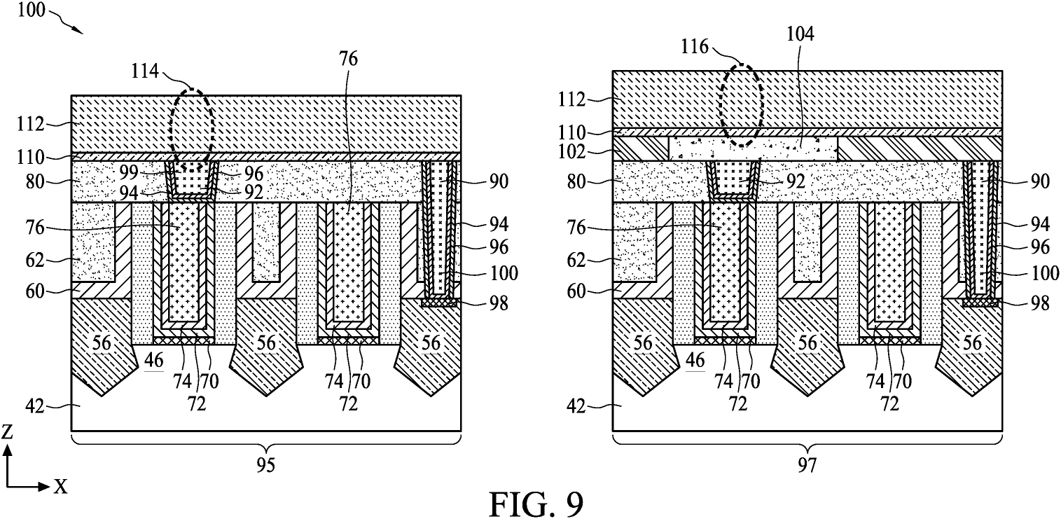

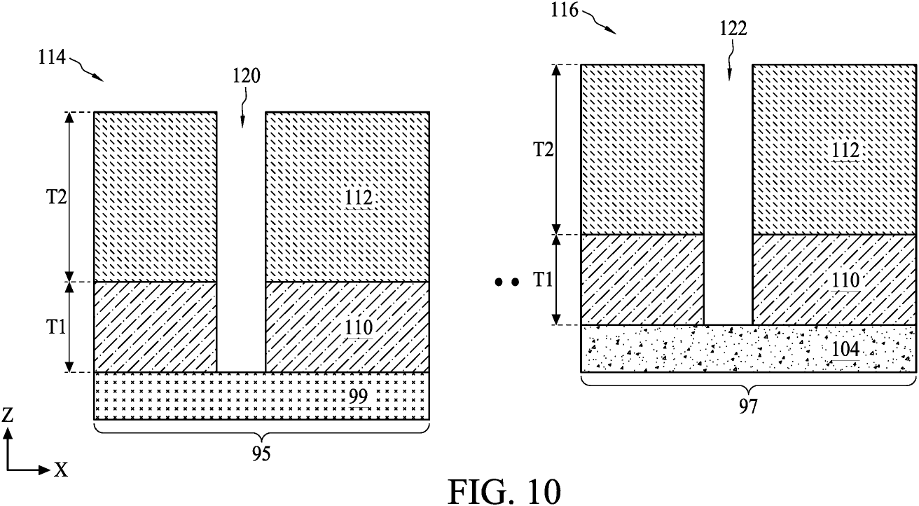

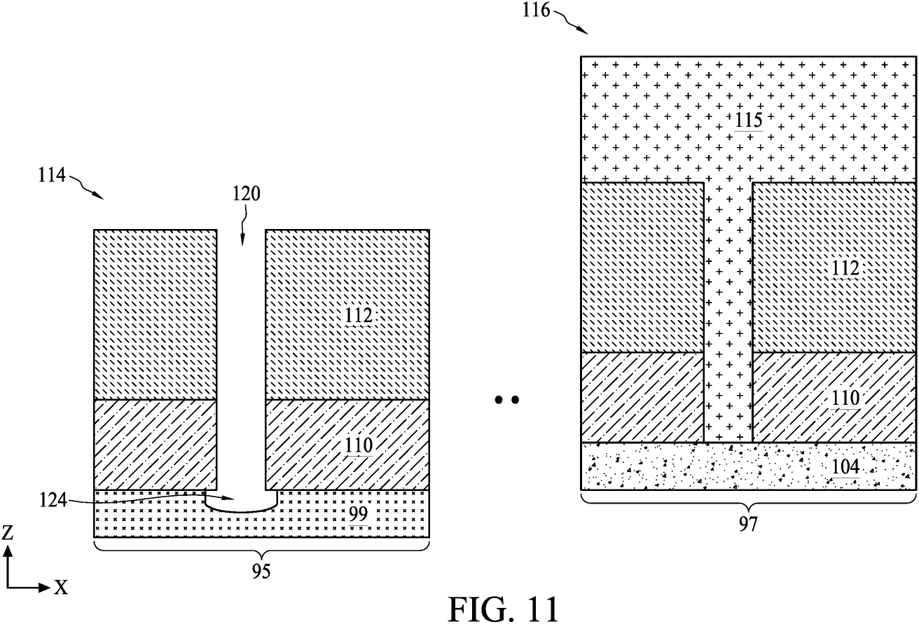

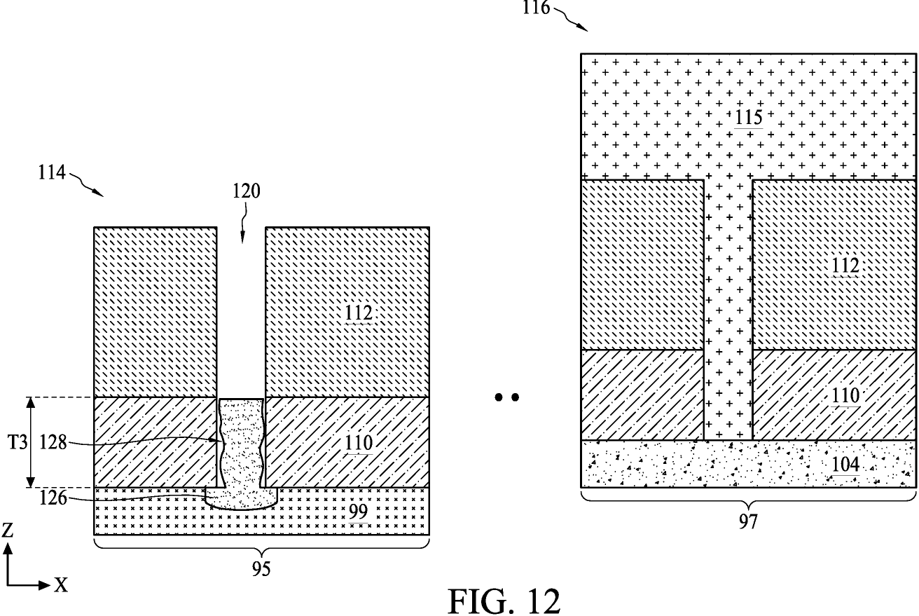

FIG. 9 illustrates the formation of an ESL 110 and an intermetallization dielectric (IMD) 112 over the ESL 110. The ESL 110 is deposited on top surfaces of the second ILD 80 and conductive features 90 and 92 in the active region 95 and is deposited on top surfaces of the dielectric layer 102 and resistor layer 104 in the resistor region 97. The ESL 110 may include or be silicon nitride, silicon carbon nitride, silicon carbon oxide, carbon nitride, the like, or a combination thereof, and may be deposited by CVD, plasma enhanced CVD (PECVD), ALD, or another deposition technique. The IMD 112 may include or be silicon dioxide, a low-k dielectric material, silicon oxynitride, PSG, BSG, BPSG, USG, FSG, OSG, SiOₓC_{y}, spin-on-glass, spin-on-polymers, silicon carbon material, a compound thereof, a composite thereof, the like, or a combination thereof. The IMD 112 may be deposited by spin-on, CVD, flowable CVD (FCVD), PECVD, PVD, or another deposition technique. A thickness of the ESL 110 can be in a range from about 15 nm to about 25 nm, and a thickness of the IMD 112 can be in a range from about 40 nm to about 60 nm. A combined thickness of the IMD 112 and ESL 110 can be in a range from about 55 nm to about 85 nm. Portions 114, 116 of the active region 95 and resistor region 97, respectively, are enlarged and shown in FIGS. 10 - 18.

As shown in FIG. 10, the portion 116 of the resistor region 97 is located at a higher elevation than the portion 114 of the active region 95 due to the existence of the resistor layer 104. An opening 120 is formed in the IMD 112 and the ESL 110 to expose a portion of the conductive fill material 99 in the active region 95, and an opening 122 is formed in the IMD 112 and the ESL 110 to expose a portion of the resistor layer 104 in the resistor region 97. The openings 120, 122 may be formed by any suitable process, such as one or more etch processes. The etch process may include a reactive ion etch (RIE), neutral beam etch (NBE), inductively coupled plasma (ICP) etch, capacitively coupled plasma (CCP) etch, ion beam etch (IBE), the like, or a combination thereof. The etch process may be anisotropic. As described above, the thickness T1 of the ESL 110 can be in a range from about 15 nm to about 25 nm, and the thickness T2 of the IMD 112 can be in a range from about 40 nm to about 60 nm. A combined thickness of the IMD 112 and ESL 110 can be in a range from about 55 nm to about 85 nm.

As shown in FIG. 11, a recess 124 is formed in the conductive fill material 99. After the openings 120, 122 are formed, a wet cleaning process may be performed to remove residue as well as native oxides from the conductive fill material 99 and the resistor layer 104. The residue may come from the etching byproduct while forming the openings 120, 122 in the previous operation steps. The residue may also come from the environment when transferring the substrate between different processing chambers while forming the IMD 112 and ESL 110. Furthermore, native oxides are often formed on the surfaces of the conductive fill material 99 and the resistor layer 104. The wet cleaning process is performed to efficiently remove the residue as well as the native oxides from the conductive fill material 99 and the resistor layer 104. Furthermore, the wet cleaning process also etches the surface of the conductive fill material 99 to form the recess 124 on the surface of the conductive fill material 99 after the residue and/or native oxide are removed therefrom. The resistor layer 104 may not be affected by the wet clean process due to the material of the resistor layer 104 being different from the material of the conductive fill material 99. The recess 124 may have a depth in the Z-direction ranging from about 3 nm to about 5 nm. In some embodiments, as shown in FIG. 11, the opening 120 and the recess 124 together form a rivet-shaped space.

As shown in FIG. 11, a mask layer 115 is formed in the resistor region 97 after the wet clean process. The mask layer 115 may be or include one or more photoresist layers. The mask layer 115 may be first formed in both the active region 95 and the resistor region 97, and then a patterning process is performed to remove the portion of the mask layer 115 formed in the active region 95. The mask layer 115 is formed on the IMD 112 and fills the opening 122 in the resistor region 97.

FIG. 12 illustrates the partial formation of a conductive feature 126 in the opening 120, in connection with the conductive fill material 99. Prior to forming the conductive feature 126, a hydrogen treatment may be performed on the exposed conductive fill material 99 to reduce any oxidized portion of the conductive fill material 99. The conductive feature 126 is formed on the surface of the conductive fill material 99 to fill the recess 124 and is formed in a bottom-up manner for filling the opening 120.

In an example, the conductive feature 126 can be deposited in the rivet-shaped space (i.e., the opening 120 and the recess 124) by CVD, ALD, electroless deposition (ELD), PVD, electroplating, or another deposition technique. In some embodiments, the conductive feature 126 is rivet-shaped. In a specific example, the conductive feature 126 is formed by a thermal CVD process, without plasma generated during the deposition process. It is believed that a thermal CVD process may provide thermal energy to assist forming nucleation sites for forming the conductive feature 126. The thermal energy provided from the thermal CVD process may promote incubation of the nucleation sites at a relatively long period of time. As the deposition rate is controlled at a relatively low deposition rate, such as less than 15 angstroms per second, the slow growing process allows the nucleation sites to slowly grow into the conductive feature 126. The low deposition rate may be controlled by supplying a deposition gas mixture with a relatively low metal precursor ratio in a hydrogen dilution gas mixture. The nucleation sites are prone to form at certain locations of the substrate having similar material properties to the nucleation sites. For example, as the nucleation sites includes metal materials for forming the conductive feature 126, the nucleation sites are then prone to adhere and nucleate on the metal materials (e.g., the conductive fill material 99). Once the nucleation sites are formed at the selected locations, the elements/atoms may then continue to adhere and anchor on the nucleation sites, piling up the elements/atoms at the selected locations, of the semiconductor substrate 42, providing a selective deposition process, as well as bottom-up deposition process.

The conductive feature 126 may be or include tungsten, cobalt, copper, ruthenium, aluminum, gold, silver, alloys thereof, the like, or a combination thereof. FIG. 12 depicts that the conductive feature 126 partially fills the opening 120 using the bottom-up process. In an example, the bottom-up thermal chemical deposition process may be obtained by controlling a process pressure less than about 150 Torr, such as from about 5 Torr to about 100 Torr, for example about 20 Torr. The process temperature may be controlled in a range from about 200° C. to about 400° C. A deposition gas mixture including at least a metal precursor and a reacting gas is used. In a specific example, the metal precursor is a tungsten containing precursor when the conductive feature 126 is a tungsten containing material. In an example, the deposition gas mixture includes WF₆. Other reacting gas, such as H₂, N₂, NH₃ and the like may also be supplied in the deposition gas mixture. In a specific example, the deposition gas mixture includes WF₆ and H₂. The reacting gas and the metal precursor may be supplied in the deposition gas mixture at a ratio greater than 20. For example, the WF₆ and H₂ may be supplied at a hydrogen gas dilution process. For example, the flow amount by volume of H₂ gas supplied in the deposition gas mixture is greater than WF₆ gas flow amount by volume. The flow amount by volume of H₂ gas is at least about 20 times greater than the flow amount by volume of WF₆ gas. In a specific example, a ratio of the flow amount by volume of H₂ gas to the flow amount by volume of WF₆ gas is from about 30 to about 150, such as from about 40 to about 120.

In some embodiments, gaps 128 may be formed between the conductive feature 126 and the ESL 110 (and the IMD 112 if the thickness T3 of the conductive feature 126 over the conductive fill material 99 is greater than the thickness T1 of the ESL 110). The thickness T3 of the portion of the conductive feature 126 ranges from about 5 nm to about 25 nm. In some embodiments, the thickness T3 is substantially the same as the thickness T1 of the ESL 110. The gaps 128 may be a result of the bottom-up selective deposition process, because the conductive feature 126 does not substantially grow on the ESL 110. In order to seal the gaps 128, a sealing portion 130 is formed around a top portion of the partially formed conductive feature 126, as shown in FIG. 13. The sealing portion 130 may be formed by an argon treatment process. The argon treatment process includes using argon to bombard the partially formed conductive feature 126, causing a portion of the conductive feature 126 to break from the conductive feature 126 and to form the sealing portion 130. In other words, the argon sputters a portion of the conductive feature 126, and the portion of the conductive feature 126 forms the sealing portion 130 to seal the gaps 128.

As shown in FIG. 14, the additional conductive feature 126 is formed to fill the opening 120. The additional conductive feature 126 may be formed using the same process as the process for forming the partial conductive feature 126 shown in FIG. 12. In some embodiments, a bottom-up selective deposition is performed. Similarly, gaps 132 may be formed between the portion of the conductive feature 126 and the IMD 112 as a result of the bottom-up selective deposition. The conductive feature 126 may extend above the level of the top surface of the IMD 112, as shown in FIG. 14.

As shown in FIG. 15, a germanium implantation process is performed, and the IMD 112 is expanded to fill the gaps 132. In other words, the IMD 112 is expanded by the germanium implantation process to squeeze the conductive feature 126. The gaps 132 are filled by the expanded IMD 112. In some embodiments, implantation of other material may be used to expand the IMD 112. However, the gaps 128 may still remain between the portion of the conductive feature 126 and the ESL 110, because the ESL 110 is not expanded by the implantation process.

As shown in FIG. 16, the mask layer 115 is removed, and the opening 122 reappears. The mask layer 115 may be removed by any suitable process. The removal of the mask layer 115 does not substantially affect the IMD 112 and the conductive feature 126.

As shown in FIG. 17, a cap structure 138 is formed on the IMD 112 in both the active region 95 and the resistor region 97, and a conductive material 144 is formed on the cap structure 138. The cap structure 138 and the conductive material 144 are also formed in the opening 122 in the resistor region 97. The cap structure 138 includes a metal layer 140 and a metal nitride layer 142 formed on the metal layer 140. The metal layer 140 may function as a barrier layer to prevent the diffusion of the conductive material 144 into the IMD 112, and the metal nitride layer 142 may function as a glue layer for the conductive material 144 to adhere thereto. In some embodiments, the metal layer 140 is formed by a PVD process having good bottom coverage. As a result, the thickness of the metal layer 140 in the Z-direction may be substantially greater than the thickness of the metal layer 140 in the X-direction. In other words, the thickness of the portions of the metal layer 140 formed on horizontal surfaces may be substantially greater than the thickness of the portions of the metal layer 140 formed on vertical surfaces. For example, the portion of the metal layer 140 formed at the bottom of the opening 122 in the resistor region 97 is thicker than the portion of the metal layer 140 formed on the sidewall of the opening 122. The metal layer may include or be any suitable metal, such as titanium. In some embodiments, the thickness of the metal layer 140 in the Z-direction ranges from about 2.5 nm to about 7.5 nm.

The metal nitride layer 142 is formed by a deposition process followed by a treatment process. The metal nitride layer 142 may be a conformal layer. In some embodiments, the metal nitride layer 142 is a titanium nitride layer and is formed by a CVD process followed by a plasma treatment process. For example, the CVD process is a PECVD process including introducing precursors into a processing chamber and forming a plasma in the processing chamber. In some embodiments, the metal nitride layer is titanium nitride, and the precursors includes a titanium-containing precursor and a nitrogen-containing precursor. For example, the titanium-containing precursor may be tetrakis(dimethylamido)titanium(IV) (TDMAT) or titanium tetrachloride (TiCl₄), and the nitrogen-containing precursor may be nitrogen gas. The processing temperature may be under 420° C., such as from about 350° C. to about 410° C. The PECVD process forms the metal nitride layer 142, such as a titanium nitride layer.

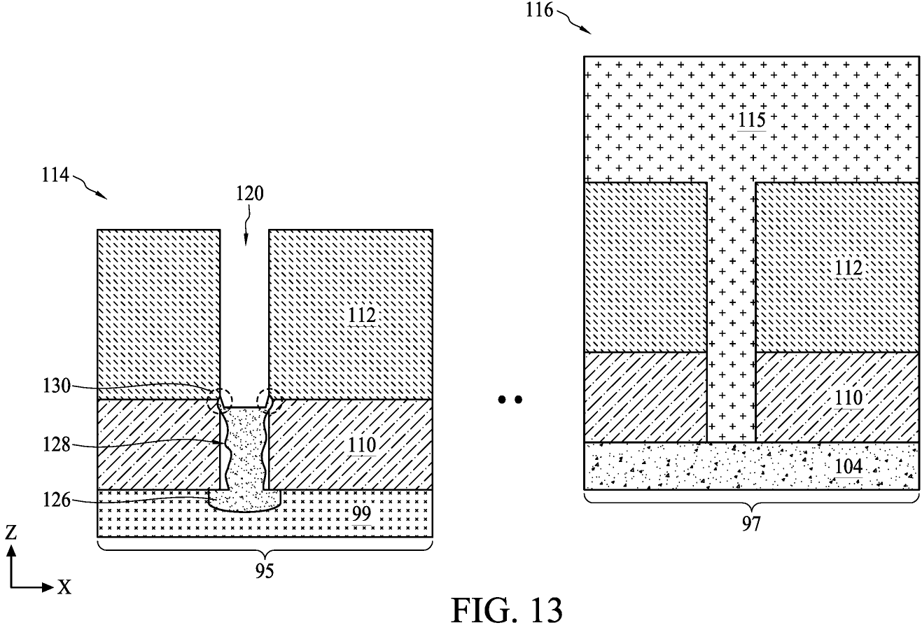

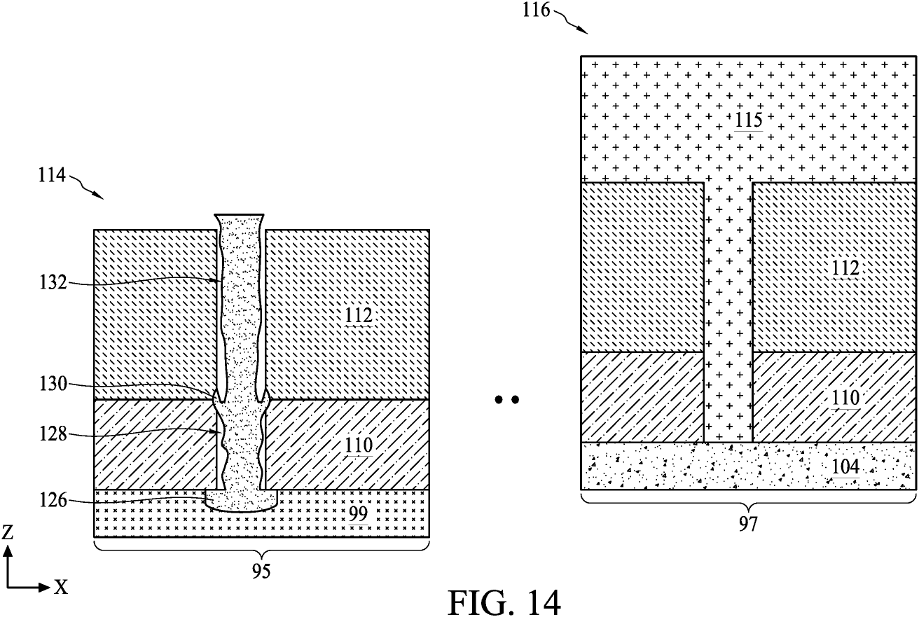

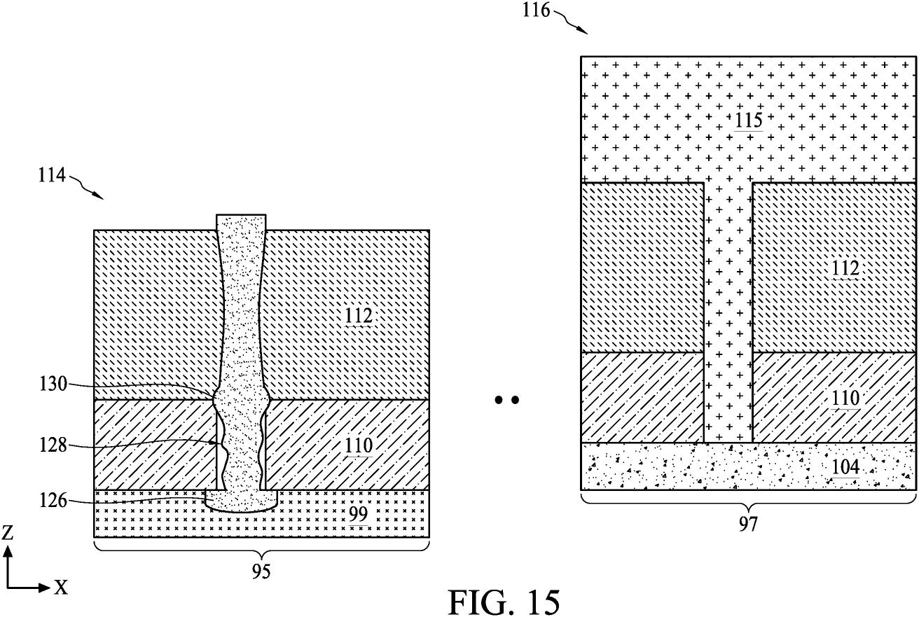

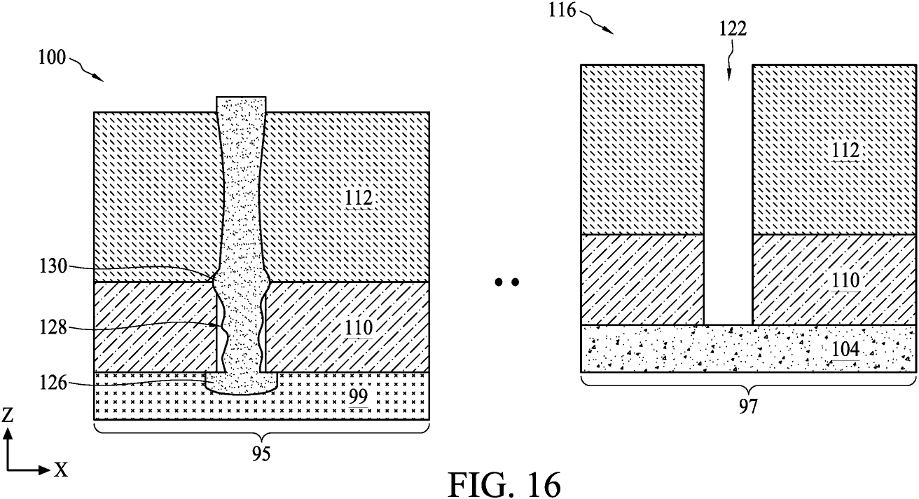

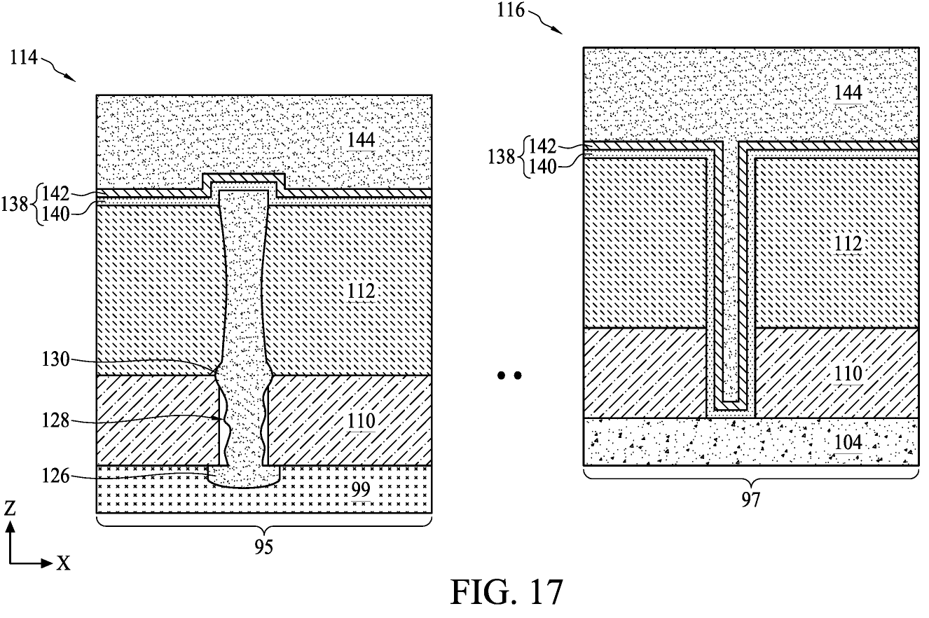

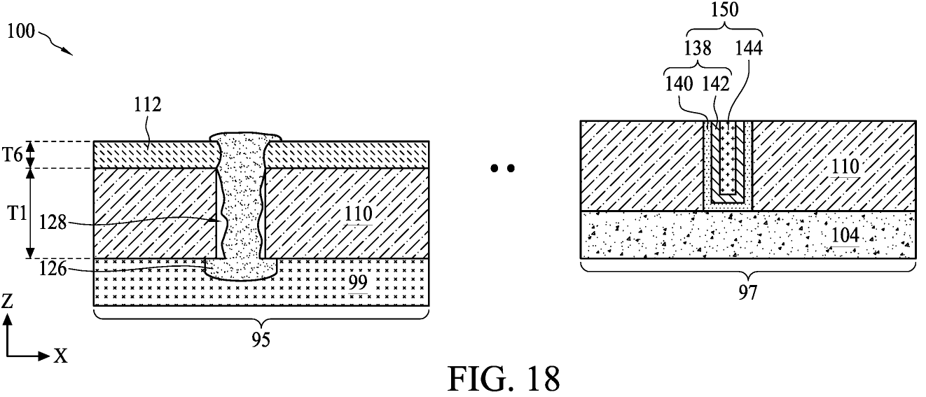

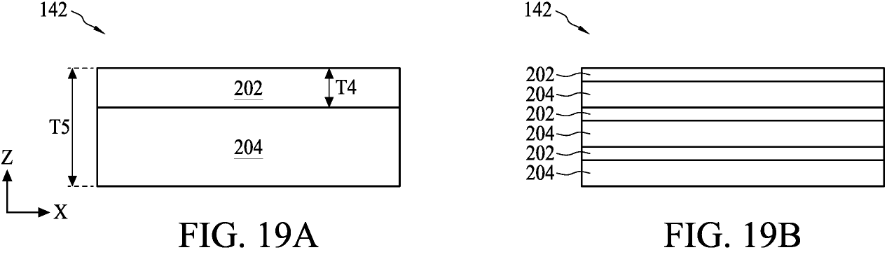

After the PECVD process, a plasma treatment process is performed on the metal nitride layer 142 to densify the metal nitride layer 142 and to remove any byproducts from the titanium-containing precursor. For example, TDMAT is used as the titanium-containing precursor, and the plasma treatment process is performed to remove carbon-containing byproducts and hydrocarbons from the TDMAT. The plasma treatment process includes introducing nitrogen gas and hydrogen gas into the processing chamber and forming a plasma in the processing chamber. The plasma treatment process also increases the nitrogen concentration in a top portion 202 (FIGS. 19A and 19B) of the metal nitride layer 142. FIGS. 19A and 19B are enlarged views of a portion of the metal nitride layer 142, in accordance with some embodiments. As shown in FIG. 19A, in some embodiments, the metal nitride layer 142 includes a top portion 202 having a first nitrogen concentration and a bottom portion 204 having a second nitrogen concentration, and the first nitrogen concentration is substantially greater than the second nitrogen concentration. In some embodiments, the top portion 202 has a thickness T4 that is about 10 percent to about 50 percent of a thickness T5 of the metal nitride layer 142. If the thickness T4 of the top portion of the metal nitride layer 142 is less than about 10 percent of the thickness T5 of the metal nitride layer 142, the metal nitride layer 142 may not be dense enough to prevent slurry from leaking through during the subsequent CMP process. On the other hand, if the thickness T4 of the top portion of the metal nitride layer 142 is greater than about 50 percent of the thickness T5 of the metal nitride layer 142, the metal nitride layer 142 may have increased electrical resistance. In some embodiments, the thickness T5 of the metal nitride layer 142 ranges from about 1 nm to about 3 nm, and the thickness T4 of the top portion of the metal nitride layer 142 ranges from about 0.5 nm to about 1.5 nm.

In some embodiments, multiple cycles of the PECVD process and plasma treatment process are performed to reach the predetermined thickness T5. In such embodiment, the metal nitride layer 142 may include multiple portions 202 having higher nitrogen concentration and multiple portions 204 having lower nitrogen concentration alternately stacked, as shown in FIG. 19B.

As shown in FIG. 18, a CMP process is performed to remove the conductive material 144, the cap structure 138, and portions of the IMD 112 and the conductive feature 126 in the active region 95. The CMP process also removes portions of the conductive material 144, the cap structure 138, and some or all of the IMD 112 in the resistor region 97. The cap structure 138 protects the materials disposed therebelow from the slurry of the CMP process. Without the metal nitride layer 142 formed using the CVD process and the plasma treatment process, the slurry from the CMP process may leak down to the gaps 128 and damage the conductive feature 126 and the conductive fill material 99. The slurry for the CMP process when removing the conductive material 144 in the active region 95 may damage the conductive feature 126 and the conductive fill material 99. After removing the conductive material 144 in the active region 95, a different slurry is used in the CMP process to remove the portion of the IMD 112. The slurry used to remove the cap structure 138 and the portion of the IMD 112 does not substantially damage the conductive fill material if leaked through. After the CMP process, the IMD 112 in the active region 95 has a thickness T6 ranging from about 10 nm to about 20 nm. In some embodiments, the thickness T6 is substantially less than the thickness T1 of the ESL 110. Because the ESL 110 and the IMD 112 are located at a higher level in the resistor region 97 due to the existence of the resistor layer 104, the IMD 112 in the resistor region 97 may be completely removed, as shown in FIG. 18. In some embodiments, a top surface of the IMD 112 in the active region and a top surface of the ESL 110 in the resistor region 97 is substantially coplanar. The conductive material 144 and the cap structure 138 may be referred to as a conductive feature 150, such as a conductive contact or a conductive plug, to electrically connect to the resistor layer 104. The conductive material 144, the ESL 110, and the cap structure 138 may be substantially coplanar in the resistor region 97.

The present disclosure provides the semiconductor device structure 100 and the methods of forming the same. In some embodiments, the semiconductor device structure 100 includes a resistor region 97 having a resistor layer 104 and a conductive feature 150 disposed thereon. The conductive feature 150 includes a conductive material 144 and a metal nitride layer 142. The metal nitride layer 142 includes a top portion 202 having a first nitrogen concentration and a bottom portion 204 having a second nitrogen concentration substantially less than the first nitrogen concentration. The different nitrogen concentrations is a result of a method to form the metal nitride layer 142, which includes a plasma treatment process after a CVD process. Some embodiments may achieve advantages. For example, the method to form the metal nitride layer 142 leads to a denser metal nitride layer 142, which provides a better protection of the materials disposed therebelow during subsequent CMP process.

An embodiment is a method. The method includes forming a first conductive feature over a substrate, and the first conductive feature includes a conductive fill material. The method further includes forming an etch stop layer on the conductive fill material, forming an intermetallization dielectric on the etch stop layer, forming an opening in the etch stop layer and the intermetallization dielectric to expose a portion of the conductive fill material, forming a recess in the exposed portion of the conductive fill material, and the opening and the recess together form a rivet-shaped space. The method further includes forming a second conductive feature in the rivet-shaped space. The second conductive feature is rivet-shaped. The method further includes forming a metal nitride layer over the intermetallization dielectric and the second conductive feature. The forming the metal nitride layer includes depositing the metal nitride layer and treating the metal nitride layer with a plasma treatment process. The method further includes performing a planarization process to remove the metal nitride layer.

Another embodiment is a method. The method includes forming a first conductive feature in an active region over a substrate. The first conductive feature includes a conductive fill material. The method further includes forming a resistor layer in a resistor region over a substrate, forming an etch stop layer on the conductive fill material and the resistor layer, forming an intermetallization dielectric on the etch stop layer, forming a first opening in the etch stop layer and the intermetallization dielectric to expose a portion of the conductive fill material, forming a second opening in the etch stop layer and the intermetallization dielectric to expose a portion of the resistor layer, and forming a second conductive feature in the first opening. The second conductive feature extends over a top surface of the intermetallization dielectric. The method further includes forming a metal nitride layer over the intermetallization dielectric and the second conductive feature and in the second opening. The forming the metal nitride layer includes depositing the metal nitride layer and treating the metal nitride layer with a plasma treatment process to increase a nitrogen concentration in a top portion of the metal nitride layer. The method further includes performing a planarization process to remove portions of the metal nitride layer disposed over the intermetallization dielectric and a portion of the second conductive feature.

A further embodiment is a semiconductor device structure. The structure includes a first conductive feature disposed in an active region over a substrate. The first conductive feature includes a conductive fill material. The semiconductor device structure further includes a resistor layer disposed in a resistor region over the substrate, an etch stop layer disposed over the first conductive feature and the resistor layer, and a second conductive feature disposed in the etch stop layer in the active region. The second conductive feature is in contact with the first conductive feature. The semiconductor device structure further includes a metal nitride layer disposed in the etch stop layer in the resistor region over the resistor layer. The metal nitride layer includes a first portion having a first nitrogen concentration and a second portion having a second nitrogen concentration substantially less than the first nitrogen concentration. The semiconductor device structure further includes a conductive material disposed in the etch stop layer, and the conductive material is in contact with the metal nitride layer. [0060] The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a first conductive feature over a substrate, the first conductive feature comprising a conductive fill material;
forming an etch stop layer on the conductive fill material;
forming an intermetallization dielectric on the etch stop layer;
forming an opening in the etch stop layer and the intermetallization dielectric to expose a portion of the conductive fill material;
forming a recess in the exposed portion of the conductive fill material, wherein the opening and the recess together form a rivet-shaped space;
forming a second conductive feature in the rivet-shaped space, wherein the second conductive feature is rivet-shaped;
forming a metal nitride layer over the intermetallization dielectric and the second conductive feature, comprising:
depositing the metal nitride layer; and
treating the metal nitride layer with a plasma treatment process; and performing a planarization process to remove the metal nitride layer.

2. The method of claim 1, further comprising forming a metal layer on the intermetallization dielectric and the second conductive feature, wherein the metal nitride layer is formed on the metal layer.

3. The method of claim 2, wherein the metal layer comprises titanium and the metal nitride layer comprises titanium nitride.

4. The method of claim 3, wherein the depositing the metal nitride layer is performed by a plasma enhanced chemical vapor deposition process.

5. The method of claim 4, wherein the plasma enhanced chemical vapor deposition process comprises introducing a titanium-containing precursor and a nitrogen-containing precursor into the processing chamber and forming a first plasma in a processing chamber.

6. The method of claim 5, wherein the plasma treatment process comprises introducing a nitrogen gas and a hydrogen gas into the processing chamber and forming a second plasma in the processing chamber.

7. The method of claim 1, wherein the planarization process is a chemical mechanical planarization process.

8. The method of claim 7, wherein a portion of the intermetallization dielectric is removed by the planarization process.

9. A method, comprising:
forming a first conductive feature in an active region over a substrate, the first conductive feature comprising a conductive fill material;
forming a resistor layer in a resistor region over a substrate;
forming an etch stop layer on the conductive fill material and the resistor layer;
forming an intermetallization dielectric on the etch stop layer;
forming a first opening in the etch stop layer and the intermetallization dielectric to expose a portion of the conductive fill material;
forming a second opening in the etch stop layer and the intermetallization dielectric to expose a portion of the resistor layer;
forming a second conductive feature in the first opening, wherein the second conductive feature extends over a top surface of the intermetallization dielectric;
forming a metal nitride layer over the intermetallization dielectric and the second conductive feature and in the second opening, comprising:
depositing the metal nitride layer; and
treating the metal nitride layer with a plasma treatment process to increase a nitrogen concentration in a top portion of the metal nitride layer; and
performing a planarization process to remove portions of the metal nitride layer disposed over the intermetallization dielectric and a portion of the second conductive feature.

10. The method of claim 9, further comprising forming a mask layer in the second opening before forming the second conductive feature in the first opening.

11. The method of claim 10, wherein forming the second conductive feature comprises: forming a first portion in a recess in the conductive fill material;
forming a second portion on the first portion, wherein first gaps are formed between the second portion and the etch stop layer;
forming a sealing portion around a top portion of the second portion; and
forming a third portion on the second portion, wherein second gaps are formed between the third portion and the intermetallization dielectric.

12. The method of claim 11, further comprising expanding the intermetallization dielectric to remove the second gaps.

13. The method of claim 12, further comprising removing the mask layer after expanding the intermetallization dielectric and prior to forming the metal nitride layer.

14. The method of claim 9, further comprising forming a metal layer on the intermetallization dielectric and the second conductive feature and in the second opening, wherein the metal nitride layer is formed on the metal layer.

15. The method of claim 9, wherein the plasma treatment process comprises introducing a nitrogen-containing gas and a hydrogen-containing gas into a processing chamber and forming a plasma in the processing chamber.

16. A semiconductor device structure, comprising:
a first conductive feature disposed in an active region over a substrate, wherein the first conductive feature comprises a conductive fill material;
a resistor layer disposed in a resistor region over the substrate;
an etch stop layer disposed over the first conductive feature and the resistor layer;
a second conductive feature disposed in the etch stop layer in the active region, wherein the second conductive feature is in contact with the first conductive feature;
a metal nitride layer disposed in the etch stop layer in the resistor region over the resistor layer, wherein the metal nitride layer comprises a first portion having a first nitrogen concentration and a second portion having a second nitrogen concentration substantially less than the first nitrogen concentration; and
a conductive material disposed in the etch stop layer, wherein the conductive material is in contact with the metal nitride layer.

17. The semiconductor device structure of claim 16, further comprising a metal layer disposed between the etch stop layer and the metal nitride layer and between the resistor layer and the metal nitride layer.

18. The semiconductor device structure of claim 17, wherein the metal layer comprises titanium and the metal nitride layer comprises titanium nitride.

19. The semiconductor device structure of claim 16, further comprising an intermetallization dielectric disposed on the etch stop layer in the active region.

20. The semiconductor device structure of claim 19, wherein a top surface of the intermetallization dielectric in the active region and a top surface of the etch stop layer in the resistor region are substantially coplanar.
